(19) United States
(12) Patent Application Publication
(10) Pub. No.: US 2010/0073037 A1
(43) Pub. Date: Mar. 25, 2010

(54) OUTPUT IMPEDANCE CONTROL CIRCUIT

(75) Inventor: Lokesh Kumath, Bangalore (IN)

Correspondence Address: Townsend and Townsend and Crew LLP / Intersil, Two Embarcadero Center, 8th Floor, San Francisco, CA, 94111, US

(73) Assignee: Intersil Americas Inc., Milpitas, CA (US)

(21) Appl. No.: 12/419,869

(22) Filed: Apr. 7, 2009

Related U.S. Application Data
(60) Provisional application No. 61/099,712, filed on Sep. 24, 2008.

(51) Int. Cl. H03B 1/00

(52) U.S. Cl. 327/108

(57) ABSTRACT

An external resistive element is used to provide a substantially constant output impedance for multiple drivers disposed on an IC. The drivers may operate at different supply voltages. Accordingly, the parameters which depend on the driver output impedance, such as rise/fall time, propagation delay, and the like are made substantially constant and independent of the semiconductor process variations, operating supply voltages, and the temperature. The substantially constant output impedance maintains the stability of the crossing point of a true and its complementary clock signal in high-speed applications, such as in the drivers used in charge-coupled devices. A number of feedback loops are used together with the external resistive element to achieve the substantially constant output impedance. The feedback loops compensate for the ageing effects, temperature gradients and changes in the operating conditions of the IC.

### CROSS-REFERENCES TO RELATED APPLICATIONS

The present application claims benefit under 35 USC 119(e) of U.S. provisional application No. 61/099,712, filed Sep. 24, 2008, entitled “Output Impedance Control Circuit”, the content of which is incorporated herein by reference in its entirety.

### BACKGROUND OF THE INVENTION

An integrated circuit (IC) often includes a number of output drivers to transfer data from the IC to another electronic device. In many applications, controlling the impedance of an output driver is critical in maintaining the integrity of the data being transmitted. For example, mismatches in the impedance of an input/output (I/O) pad and the transmission line to which the pad is connected causes signal reflections during voltage level switching of the data. The signal reflections may result in undesirable signal degradation. Output impedance mismatches may occur for a number of reasons. For example, as the manufacturing process, operating temperature, and voltage supply rails vary, the output impedance of the I/O pins may also vary.

### BRIEF SUMMARY

A control circuit, in accordance with one embodiment of the present invention, includes, in part, at least one internal resistive element and a first circuit adapted to generate first and second control signals in response to a ratio of the resistances of the internal resistive element and an external resistive element. The first and second control signals are adapted to cause the output impedance of an output driver to be substantially the same as or proportional to the resistance of the external resistive element.

### BRIEF DESCRIPTION OF THE DRAWINGS

FIG. 1 is a high-level block diagram of a circuit adapted to provide a substantially constant output impedance for a multitude of output drivers, in accordance with one exemplary embodiment of the present invention.

FIG. 2 is a block diagram of a circuit adapted to provide a substantially constant output impedance for a multitude of output drivers of an IC, in accordance with one exemplary embodiment of the present invention.

FIG. 3A is a block diagram of a current generator disposed in the circuit of FIG. 2, in accordance with one exemplary embodiment of the present invention.

FIG. 3B is a block diagram of a current generator disposed in the circuit of FIG. 2, in accordance with another exemplary embodiment of the present invention.

FIG. 4 is a block diagram of a voltage-controlled current multiplier disposed in the circuit of FIG. 2, in accordance with one exemplary embodiment of the present invention.

FIGS. 5A and 5B are block diagrams of loop-control blocks disposed in the circuit of FIG. 2, in accordance with one exemplary embodiment of the present invention.

FIG. 6 shows output signals of an output driver under various operating conditions and fabrication process corners, as known in the prior art.

FIG. 7 shows output signals of an output driver under various operating conditions and fabrication process corners, in accordance with one exemplary embodiment of the present invention.

FIG. 8 shows an embodiment of a digital camera with an output driver having a controlled output impedance.

### DETAILED DESCRIPTION

In accordance with one embodiment of the present invention, a ratio of external and internal resistances is used to generate a multitude of control signals that provide a substantially constant impedance at the output terminals of a multitude of output drivers each of which may operate at different supply voltages. In one embodiment, the control signals are formed in response to a number of currents generated in proportion to the ratio of the external and internal resistances.

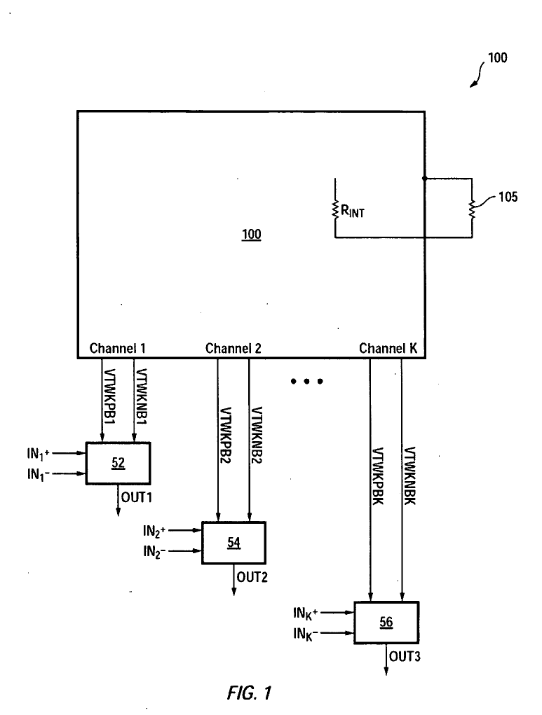

FIG. 1 is an exemplary embodiment of a circuit 100 adapted to provide K pairs of control signals in response to a ratio of an external resistor 105 and an internal resistor R_{INT}. Control signals VTWKNB₁ and VTWKPB₁ are associated with channel 1 and are shown as applied to output driver block 52; control signals VTWKNB₂ and VTWKPB₂ are associated with channel 2 and are shown as applied to output driver block 54. Likewise, control signals VTWKNB_{K} and VTWKPB_{K} are associated with channel K and are shown as applied to output driver block 56. Although not shown, it is understood that the remaining control signals associated with channels 3 through (K−1) may also be applied to other output driver blocks.

Control signals VTWKNB₁ and VTWKPB₁ cause the impedance at the output terminal of driver of block 52 to be substantially the same as or proportional to the impedance of external resistor 105. Control signals VTWKNB₂ and VTWKPB₂ cause the impedance at the output terminal of driver of block 54 to be substantially the same as or proportional to the impedance of external resistor 105. Likewise, control signals VTWKNB_{K} and VTWKPB_{K} cause the impedance at the output terminal of driver of block 56 to be substantially the same as or proportional to the impedance of external resistor 105. Output drivers 52, 54 and 56 may operate at the same or different supply voltages.

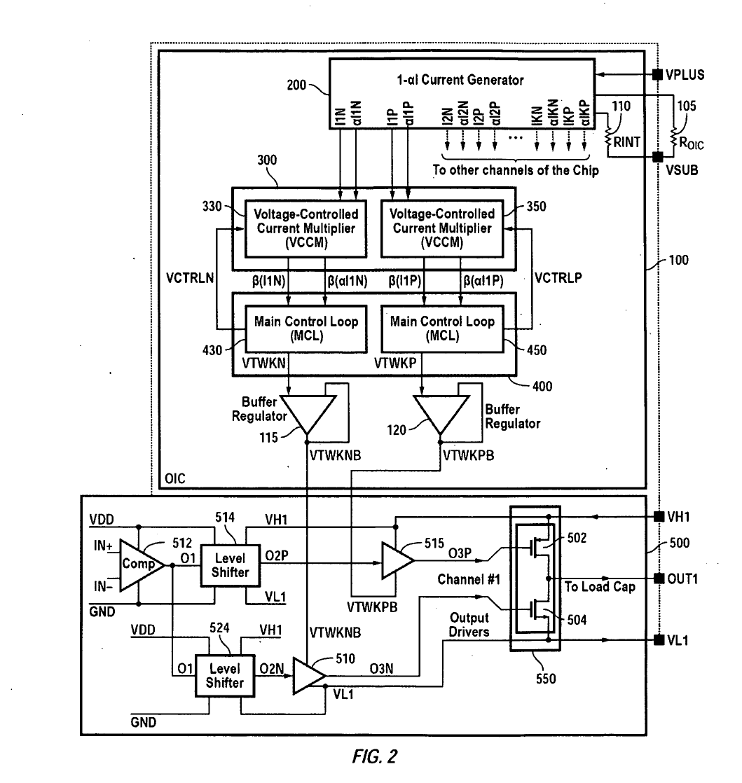

FIG. 2 is a block diagram of a circuit 100 adapted to provide a substantially constant impedance at the output terminal of each of its K output drivers that may operate at different supply voltages. Each output driver is shown in FIG. 2 as being associated with a different one of K channels. The output impedance of the output drivers of circuit 500 is controlled by using an external resistance 105 as a reference resistor. Although the detailed schematics associated with only one such channel, namely channel 1, and its associated output path circuitry 500 are shown in FIG. 2, it is understood that the remaining (K−1) channels are similar to channel 1.

Circuit 100 is shown as including, in part, a current generating block 200 adapted to generate 2K current pairs based on the resistances of an external resistor 105 (R_{OIC}), and the resistance of internal resistor 110 (R_{INT}) and to supply these currents to the output channels. For example, channel 1 is adapted to receive current pairs, (I_{1N}, αI_{1N}) and (I_{1P}, αI_{1P}). Channel 2 is adapted to receive current pairs, (I_{2N}, αI_{2N}) and (I_{2P}, αI_{2P}). Likewise, for example, channel K is adapted to receive current pairs, (I_{KN}, αI_{KN}) and (I_{KP}, αI_{KP}). The following description is provided with reference to the operation of channel 1 and its output path circuitry 500. It is understood, however, that the following description equally applies to other (K−1) output channels of circuit 100.

Output channel 1 is shown as including, in part, a voltage-controlled current multiplication block 300, a loop control block 400, buffers 115, 120 and output path circuitry 500. Voltage-controlled multiplication block 300 is adapted to multiply currents (I_{1N}, αI_{1N}) and (I_{1P}, αI_{1P}) by a multiplier β to generate currents β(I_{1N}, αI_{1N}) and β(I_{1P}, αI_{1P}) respectively. Current multiplier β is determined, in part, by a feedback-loop disposed in loop control block 400. Multiplier β ensures that the voltage across a resistance internal to loop control block 400, and thereby the drain-to-source voltages across a pair of reference MOS transistors also disposed in loop control block 400, are maintained such that the average impedances of the MOS output drivers in output path circuitry 500 are approximately equal, or proportional to the impedances of the reference MOS transistors, as described further below. Output voltages VTWKN and VTWKP, generated by loop control block 400, are applied to buffers 115, and 120 as shown in FIG. 2.

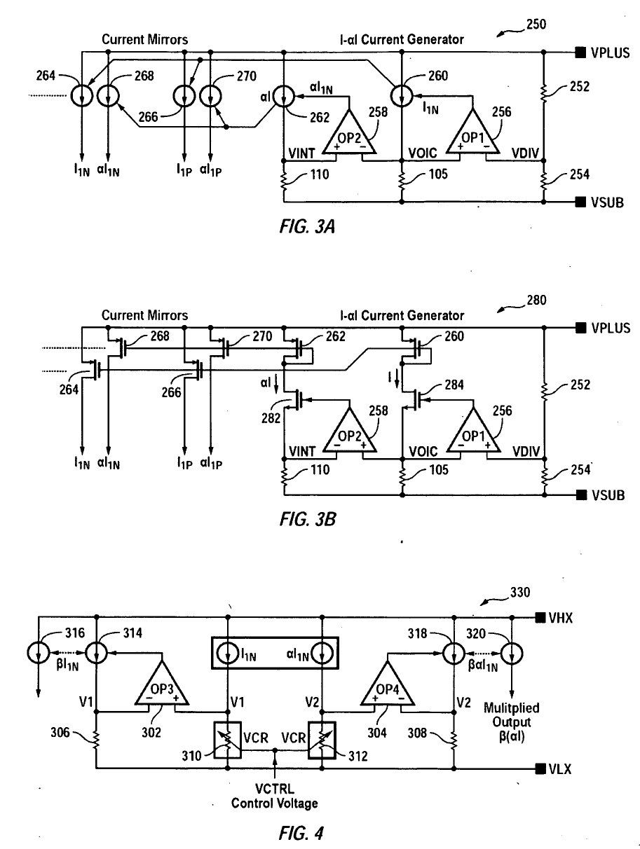

FIG. 3A is a block diagram of current generator 250 disposed in current generating block 200 and adapted to generate current pairs (I_{1N}, αI_{1N}) and (I_{1P}, αI_{1P}) for channel number 1. Although not shown, it is understood that the current generators for other output channels are similar to current generator 250 and are disposed in current generating block 200. Current generator 250 is shown as operating between supply voltages VPLUS (the highest supply voltage on the IC on which circuit 100 is disposed) and VSUB (the lowest supply voltage on the IC on which circuit 100 is disposed) thus ensuring that the currents generated by this block are mirrored properly to the various other blocks shown in FIG. 2, irrespective of the voltages at which these blocks operate. The resistance of internal resistor 110 is typically selected to have the same value as the resistance of the external resistor 105. Current multiplication parameter a is defined, in part, by the resistances of internal resistor 110 and external resistor 105, as described further below. Internal resistor 110 may be formed using poly resistors, N-well/P-well resistors, etc. Current generator 250 is shown as also including, in part, operational amplifiers 256, 258, current mirrors 264, 266, 268, 270, and resistors 252, 254.

As shown, a fraction of the difference between VPLUS and VSUB is used to generate current I_{1N} via the negative feedback-loop across operational amplifier (op-amp) 256. The voltage divider that includes resistors 252 and 254 generates voltage V_{DIV} applied across the external resistor 105 using the feedback loop. The ratio of resistors 252 and 254 may be selected in accordance with the value of the desired current level. This ratio may depend on a number of factors, such as the range of voltages VPLUS and VSUB, the range of resistance of the external resistor 105 which can be used to vary and control the output impedance of the output drivers, and the like.

Due the feedback loop across op-amp 256, voltages V_{DIV} and V_{OIC} are at substantially the same level. Accordingly, current I_{1N} is defined by:

$${I}_{1 N} = \frac{( {V}_{PLUS} - {V}_{SUB} )}{{R}_{105}} \frac{{R}_{254}}{( {R}_{252} + {R}_{254} )} \qquad ( 1 )$$

As stated above, the resistance of internal resistor 110 is typically selected to be substantially the same as the resistance of external resistor 105. Therefore, under typical semiconductor process and temperature variations where the resistances of resistors 110 and 105 match, α is equal to 1, and therefore, αI_{1N} is substantially the same as I_{1N}. However, due to semiconductor process and temperature variations, the resistance of internal resistor 110 will change. Since resistor 105 is an external resistor, its value remains relatively constant. This will cause α to be either less than 1 or greater than 1, depending on the direction in which the resistance of resistor 110 changes. Accordingly α is defined by the following expression:

$$α = \frac{{R}_{105}}{{R}_{110}} \qquad ( 2 )$$

Consequently, when the resistance of the external resistor 105 is changed to vary the output impedance, α will change even if there is no change in the resistance of resistor 110. Due to the feedback loop across op-amp 258, voltages V_{INT} and V_{OIC} are at substantially the same level. Accordingly, current αI_{1N} is defined by:

$$α {I}_{1 N} = \frac{( {V}_{PLUS} - {V}_{SUB} )}{{R}_{110}} \frac{{R}_{254}}{( {R}_{252} + {R}_{254} )} \qquad ( 3 )$$

Current mirrors 264 and 266 mirror current I_{1N} to respectively generate currents I_{1N} and I_{1P}. Likewise, current mirrors 268 and 270 mirror current αI_{1N} to respectively generate currents αI_{1N} and αI_{1P}.

FIG. 3B is a block diagram of current generator 280 disposed in current generating block 200 and adapted to generate current pairs (I_{1N}, αI_{1N}) and (I_{1P}, αI_{1P}) for channel number 1, in accordance with another exemplary embodiment of the present invention. Current mirrors 264, 266, 268 and 270 of current generator 280 are shown as being formed using PMOS transistors. Current sources 260 and 262 are also shown as being formed using PMOS transistors. To reduce the number of poles, NMOS transistor 282 which forms a source follower amplification stage is disposed between transistor 262 and resistor 110, and NMOS transistor 284 which forms a source follower amplification stage is disposed between transistor 260 and resistor 105. The drain terminal of NMOS transistor 282 is coupled to the drain terminal of PMOS transistor 262. Likewise, the drain terminal of NMOS transistor 284 is coupled to the drain terminal of PMOS transistor 260. It is understood that current mirrors 264, 266, 268 and 270 may be formed using cascode or other types of current mirrors.

Referring to FIG. 2, voltage-controlled multiplication block 300 is adapted to receive and multiply currents (I_{1N}, αI_{1N}) and (I_{1P}, αI_{1P}) by a multiplication factor β, thereby to generate currents β(I_{1N}, αI_{1N}) and β(I_{1P}, αI_{1P}), respectively. Multiplication factor β is determined in accordance with the control voltages VCTRLP and VCTRLN generated respectively by main control loops (MCL) 430 and 450, as described further below.

Voltage-controlled multiplication block 300 includes a pair of similar voltage-controlled current multipliers (VCCM) 330 and 350. VCCMs 330 and 350 are respectively associated with the pull-down NMOS transistor 504 and pull-up PMOS transistor 502 disposed in output path circuitry 500. FIG. 4 is a block diagram of VCCM 330, in accordance with one exemplary embodiment of the present invention. Although not shown, it is understood that VCCM 350 is similar to VCCM 330. It is also understood that other channels of circuit 100 include a similar voltage-controlled current multiplication block.

VCCM 330 is shown as including, in part, op-amps 302, 304, voltage-controlled resistors (VCR) 310, 312, and current mirrors 314, 316, 318 and 320. Current mirrors 314 and 316 mirror current I_{1N} flowing through VCR 310. Likewise, current mirrors 318, 320 mirror current αI_{1N} flowing through VCR 312. Current I_{1N} causes voltage V1 to be generated across VCR 310. Because of the negative feedback loop across op-amp 302, substantially the same voltage V1 is also generated across resistor 306. Accordingly, current βI_{1N} flowing through current mirrors 314 and 316 is defined by the following expression:

$$β {I}_{1 N} = \frac{{I}_{1 N} {R}_{310}}{{R}_{306}} \qquad ( 4 a )$$

Current αI_{1N} causes voltage V2 to be generated across VCR 312. Because of the negative feedback loop across op-amp 304, substantially the same voltage V2 is also generated across resistor 308. Accordingly, current βαI_{1N} flowing through current mirrors 318 and 320 is defined by the following expressions:

$$β α {I}_{1 N} = \frac{α {I}_{1 N} {R}_{312}}{{R}_{308}} \qquad ( 4 b )$$

where β is defined by the ratio of the resistances of VCR 312 and resistor 308.

As mentioned above, the values of the currents I_{1N} and αI_{1N} are determined, in part, by selecting a proper voltage divider ratio for resistors 252 and 254, as shown in FIG. 3. Currents I_{1N} and αI_{1N}, in turn, determine the voltages V1 and V2 across VCRs 310 and 312. Each VCR is ideally adapted to have a suitable voltage range over which its resistance remains nearly constant for a given control voltage VCTRL.

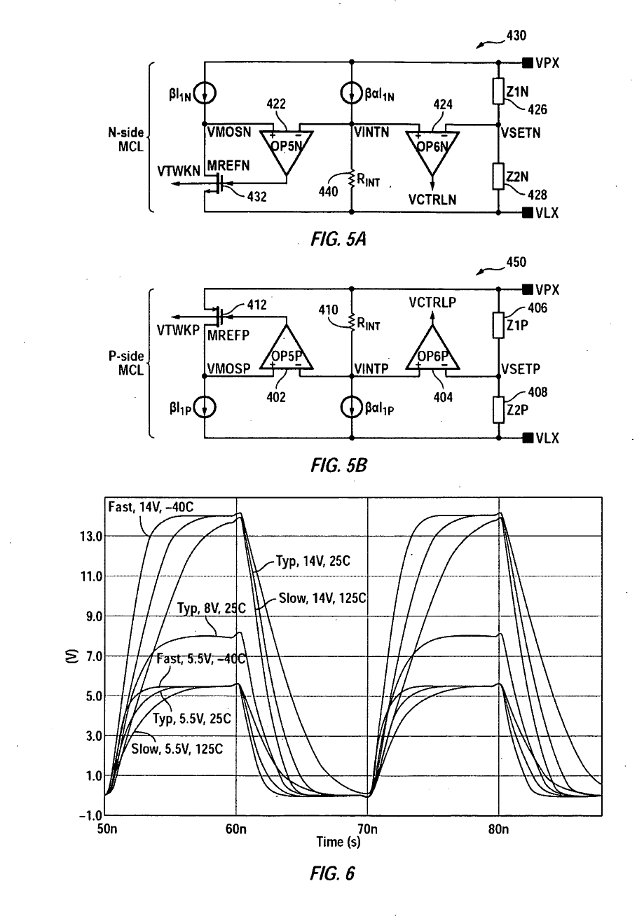

Referring to FIG. 2, loop control block 400 is shown as including a pair of similar MCLs 430 and 450. MCLs 430 and 450 are respectively associated with the pull-down NMOS transistor 504 and pull-up PMOS transistor 502 disposed in output path circuitry 500. FIGS. 5A and 5B are block diagrams of MCL 430 and 450, in accordance with one exemplary embodiment of the present invention. Although not shown, it is understood that other channels of circuit 100 include a similar loop control block.

MCLs 430 and 450 are adapted to generate the gate driver voltages VTWKN and VTWKP associated respectively with NMOS and PMOS transistors 502 and 504 disposed in output path circuitry 500. MCL 430 receives currents βI_{1N} and βαI_{1N}, and in response generates control signal VCTRLN applied to VCCM 330, and signal VTWKN applied to buffer 115. Likewise, MCL 450 receives currents βI_{1P} and βαI_{1P}, and in response generates control signal VCTRLP applied to VCCM 350, and signal VTWKP applied to buffer 120. Signals VCTRLN and VCTRLP control the current multiplication factor β of voltage-controlled current multiplication block 300. [0033] Referring to FIG. 5A, MCL 430 is shown as having two negative feedback loops. The feedback loop that includes op-amp 422 establishes the drain-to-source voltage of reference MOS transistor 432. The feedback loop that includes op-amp 424 generates voltage signal VCTRLN applied to VCCM 330. Referring to FIG. 5B, the feedback loop that includes op-amp 402 establishes the drain-to-source voltage of reference transistor 412. The feedback loop that includes op-amp 404 establishes voltage signal VCTRLP applied to VCCM 350. It is understood that VCCM 350 operates in the same manner as VCCM 330.

Referring to FIG. 5A, impedances 426 and 428 may be implemented using resistor elements, a combination of resistor elements and NMOS/PMOS devices, or a combination of NMOS and PMOS devices. Impedances 426 and 428 are selected such that the changes in voltage VSETN due to process, voltage and temperature (PVT) variations cause the resistance of the reference MOS transistor 432 to be approximately equal to, or proportional to the average resistance of the output transistor 504 for any given supply voltage, temperature and semiconductor process condition. Selecting proper values for impedances 426 and 428 is thus an important factor in improving the accuracy of circuit 100.

The feedback loop that includes op-amp 422 receives currents βI_{1N} and βαI_{1N} from VCCM block 330. Current βI_{1N} is supplied to reference MOS transistor 432, and current βαI_{1N} is supplied to resistor 440. Because of the feedback loop in which op-amp 424 is disposed, voltage VINTN is substantially equal to voltage VSETN. If, for example, voltage VINTN becomes greater than voltage VSETN, control voltage VCTRLN changes the multiplying factor β in a direction which causes a decrease in VINTN. In other words, due to the high gain of this loop, voltage VINTN is made substantially similar to voltage VSETN. Because of the feedback loop in which op-amp 422 is disposed, voltage VINTN is substantially equal to voltage VMOSN applied to the drain terminal of reference NMOS transistor 432.

Referring to FIG. 5B, because of the feedback loop in which op-amp 404 is disposed, voltage VINTP is substantially equal to voltage VSETP. If, for example, voltage VINTP becomes greater than voltage VSETP, control voltage VCTRLP changes the multiplying factor β in a direction which causes a decrease in VINTP. In other words, due to the high gain of this loop, voltage VINTP is made substantially similar to voltage VSETP. Because of the feedback loop in which op-amp 402 is disposed, voltage VINTP is substantially equal to voltage VMOSP applied to the drain terminal of reference PMOS transistor 412.

Writing the KVL equations for the two loops and taking into account other equations, it is seen that:

R_{REF}=R₁₀₅ (5)

where R_{REF} represents the impedance of reference MOS transistors 412 or 432, shown in FIGS. 5B and 5A respectively.

In other words, the impedances of the reference MOS transistors 412 and 432 is made substantially equal to the resistance of the external resistor R₁₀₅. The dimensions of reference MOS transistors 412 and 432 is a fraction of the dimensions of the output driver transistors 502 and 504. Accordingly, the impedance of each of output driver transistors 502 and 504 is a fraction of the impedance of the external resistor R₁₀₅ and is thus nearly constant.

Referring to FIG. 2, voltages VTWKP and VTWKN are respectively buffered by buffers 115 and 120, which in response, generate buffered signals VTWKPB and VTWKNB. Although not shown, it is understood that other channels of circuit 100 include similar buffers. The buffered output voltages VTWKPB and VTWKNB are supplied to buffer drivers 515 and 510, respectively.

FIG. 2 shows output path circuitry 500 associated with channel number 1 of circuit 100. Although not shown, it is understood that other channels of circuit 100 include a similar output path circuit. Output path circuit 500 is shown as including, in part, comparator 512, level shifter 514 and buffer 515 associated with PMOS pull-up transistor 502, as well as level shifter 524 and buffer 510 associated with NMOS pull-down transistor 504.

Signals IN⁺ and IN⁻ are applied to the input terminals of comparator 512. The output O1 of comparator 512 is at VDD if voltage signal IN⁺ is greater than or equal to voltage signal IN⁻, and at GND if voltage signal IN⁺ is less than voltage signal IN⁻. Output signal O1 is applied to level shifter 514, which in response, generates signal O2P. Level shifted signal O2P is either at VH1 or VL1 supply levels depending on the relative values of voltages IN⁺ and IN⁻. As shown in FIG. 2, voltage VH1 is the higher supply voltage supplied to driver buffer 515 and output driver 550. Voltage signal VTWKPB, generated by buffer 120, is the lower supply voltage supplied to driver buffer 515. Output signal O1 is also applied to level shifter 524, which in response, generates signal O2N. Level shifted signal O2N is either at VH1 or VL1 supply levels depending on the relative values of voltage signals IN⁺ and IN⁻. As shown in FIG. 2, voltage VL1 is the lower supply voltage supplied to driver buffer 510 and output driver 550. Voltage signal VTWKNB, generated by buffer 115, is the upper supply voltage supplied to driver buffer 510.

Driver buffer 515 receives signal O2P, and in response, generates buffered signal O3P adapted to vary between voltage levels VH1 and VTWKPB. Signal O3P is applied to the gate terminal of PMOS pull-up transistor 502. Driver buffer 510 receives signal O2N, and in response, generates buffered signal O3N adapted to vary between voltage levels VL1 and VTWKNB. Signal O3N is applied to the gate terminal of NMOS pull-down transistor 504. The output impedance of MOS transistors 502 and 504 is maintained substantially the same as or proportional to the impedance of external resistor 105.

Although, the circuit blocks associated only with channel number 1 is shown, it is understood that the output impedance associated with other remaining K−1 channels may be controlled using the same external resistor 105.

Without using any output impedance control, the impedance of the output transistors may change considerably due to the PVT variations. The impedance may, for example, by as high as 50-100% depending on the technology, the range of supply voltages and the temperature range. This in turn affects the rise/fall time (TR/TF) of the circuit because these parameters depend on the output impedance of the driver and the load capacitance which the driver drives. The change in the TR/TF also affects the overall propagation delay of the circuit, which is not desired in many applications like high-speed CCD drivers, etc.

Table 1 below shows the variation in the rise time (TR) and fall time (TF) of a conventional driver designed to drive a capacitive load for a range of voltages varying from 5.5V to 14V. Table 1 shows the values of the TR/TF for the typical, slow and fast process corners, supply voltage varying from 5.5V to 14V, and the temperature varying from −40° C. to +125° C. Parameter TPD represents the propagation delay associated with the PMOS and NMOS transistors of the output driver of such a conventional circuit.

TABLE 1

| Process | Supply | | | |
|---|---|---|---|---|
| corner | voltage (V) | Temperature (° C.) | TR/TF (ns) | TPD (ns) |
| Fast | 5.50 V | −40° C. | 1.7/1.9 | 0.80/0.95 |
| Fast | 14.0 V | −40° C. | 2.5/3.1 | 1.40/1.60 |
| Typical | 5.50 V | 25° C. | 2.7/2.5 | 1.10/1.20 |
| Typical | 8.00 V | 25° C. | 3.0/3.0 | 1.40/1.50 |
| Typical | 14.0 V | 25° C. | 4.0/4.0 | 2.20/2.00 |
| Slow | 5.50 V | +125° C. | 4.0/4.0 | 2.20/1.80 |
| Slow | 14.0 V | +125° C. | 6.1/5.9 | 3.30/3.00 |

FIG. 6 is a plot of the output signal of the output driver associated with the various operating conditions shown in Table 1. As can be seen from Table 1 and FIG. 6, there are considerable variations in the rise/fall time and the propagation delay of the driver. The driver in this example was optimized for achieving 3.0 ns for a given maximum gate voltage allowed by the manufacturing process, under a typical process corner, at 25° C., and at 8V of supply voltage, as shown in the Table. The TR and TF at other process corners were obtained by maintaining the gate drive voltage to a maximum constant value allowed by the process.

As is seen, at the condition identified by a slow process, temperature of 125° C., and supply voltage of 14V, the rise/fall time is 6.1 ns/5.9 ns, representing the slowest process corner. At the condition identified by a fast process, temperature of −40° C., and supply voltage of 5.5, the rise/fall time is 1.7/1.9, representing the fastest process corner. The variation in TR/TF across the designed value of 3.0 ns is about −43% and +103%. Because TR/TF is proportional to the resistance, the change in the resistance of the output drivers will be in the same proportion. Taking the mean value as 3.9 ns for the TR/TF, the variation across this value is about ±56%. Similarly, the TPD of the drivers itself is shown as varying by about 36% and +100% respectively with the typical value of about 1.5 ns. The variations in the rise and fall times of the output signal in FIG. 6 indicate the variation in the output impedance of the driver.

Table 2 shows the variation in the TR/TF of an output driver in accordance with one exemplary embodiment of the present invention.

TABLE 2

| Process | Supply voltage | | | |
|---|---|---|---|---|
| corner | (V) | Temperature (° C.) | TR/TF (ns) | TPD (ns) |
| Fast | 5.50 V | −40° C. | 2.65/2.70 | 1.65/1.70 |
| Fast | 14.0 V | −40° C. | 2.95/2.95 | 1.80/1.80 |
| Typical | 5.50 V | 25° C. | 2.70/2.75 | 1.50/1.70 |
| Typical | 8.00 V | 25° C. | 2.80/2.80 | 1.70/1.65 |
| Typical | 14.0 V | 25° C. | 2.80/2.95 | 1.70/1.65 |
| Slow | 5.50 V | +125° C. | 2.90/2.95 | 1.70/1.65 |
| Slow | 14.0 V | +125° C. | 3.00/3.00 | 1.80/1.75 |

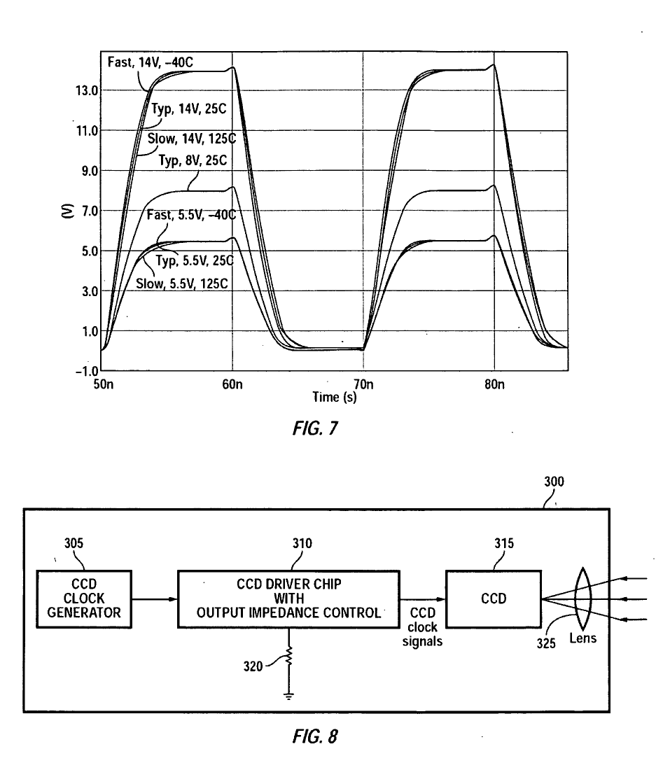

FIG. 7 is a plot of the output signal of the output driver associated with Table 2. As is seen from Table 2, there is an appreciably smaller variations in the rise/fall time and the propagation delay of the exemplary output driver of the present invention. The driver in this example is optimized for 3.0 ns for a given maximum gate voltage drive, at the slow process corner, temperature of 125° C. and supply voltage of 14V. At other process corners, the gate drive is varied in accordance with one embodiment of the present invention and the TR/TF was measured. The fastest TR/TF is 2.65/2.70 at the fast process corner, −40° C. at a supply voltage of 5.5V. The variation in TR/TF across the designed value of 3.0 ns is about −11% and +0.0% respectively. Taking the mean value as 2.825 ns, the variations across this value is about ±6%. Therefore, in accordance with the embodiments of the present invention, the percentage variation in TR/TF is reduced by nearly a factor of 10. The TPD of the drivers is seen as having varied by about −11% and +6% respectively with the typical value of about 1.7 ns.

An output impedance control circuit, in accordance with embodiments of the present invention, provides a number of advantages. First, such an output impedance control circuit provides substantially constant output impedance for multiple drivers of an integrated circuit (e.g., CCD, PIN electronics, etc.) that may operate at different supply voltages, by using a single external resistor. The output impedance control circuit provides substantially constant output impedance despite variations in temperature and fabrications processes. Second, the output impedance control circuit is advantageous when low gate-to-source voltage devices (e.g., a device with 5V Vgs) are used to achieve faster propagation delay, thus requiring a regulator circuit to fix the gate-to-source voltage of the MOS drivers. This is in contrast to the cases where a high gate-to-source voltage can be used (at the cost of higher propagation delay) and where the gate-to-source voltage is nearly equal to the driver supply voltage.

Third, the external resistor may be tuned to change the output impedance in both directions. Therefore, parameters like rise/fall time, and propagation delay which depend on the output impedance of the driver may be modified. This is important in applications where tightly controlled rise/fall time, etc. are required. Fourth, because of the external tuning feature, the same IC may be used in various applications which require a different output impedance and TR/TF of the output drivers. Fifth, an output impedance control circuit, in accordance with embodiments of the present invention, provides an on-line correction technique. In other words, the various feedback loops are adapted to continue working as long as the IC is in the active state. Accordingly, it can compensate for the ageing effects, gradient in temperature and changes in the operating conditions of the IC. Most conventional correction techniques use fuse trimming, etc. which is not an on-line correction and therefore cannot compensate for the ageing effects, etc. Conventional techniques may provide nearly constant output impedance for only those operating conditions at which the trimming was performed. At any other operating conditions, there will be variations in the output impedance of such conventional drivers. Embodiments of the present invention, on the other hand, provide substantially constant output impedance for a range of operating conditions. Sixth, an output impedance control circuit, in accordance with embodiments of the present invention, does not require any post-fabrication methods (such as fuse trimming of the output driver transistors) and thus decreases the cost and avoids extra testing time.

FIG. 8 is a simplified block diagram of a digital camera 300 with an output driver having a controlled output impedance, in accordance with one embodiment of the present invention. Digital camera is shown as including a charge coupled device (CCD) 315, a clock generator 305, a CCD driver IC 310, and a camera lens 310. CCD clock generator 305 is adapted to supply clock signals to CCD driver IC 310. The CCD driver IC 310 includes an output impedance control circuit, in accordance with embodiments of the present invention described above. The output impedance of CCD driver IC 310 is maintained substantially the same as or proportional to the impedance of resistor 320 that is external to CCD driver IC 310. Consequently, the variations in rise and the fall time of the CCD clock signal supplied by CCD driver IC to CCD 315 is substantially reduced to improve the overall performance of the camera.

The above embodiments of the present invention are illustrative and not limiting. Various alternatives and equivalents are possible. The invention is not limited by the type of current mirror, amplifier, resistor, etc., used. The invention is not limited by the number of output channels and output drivers. The invention is not limited by the type of integrated circuit in which the present disclosure may be disposed. Nor is the invention limited to any specific type of process technology, e.g., CMOS, Bipolar, or BICMOS that may be used to manufacture the present disclosure. Other additions, subtractions or modifications are obvious in view of the present disclosure and are intended to fall within the scope of the appended claims.

What is claimed is:

1. A control circuit comprising:
at least one resistive element;
an output driver; and
a first circuit adapted to generate a first control signal and a second control signal in response to a ratio of resistance of the at least one resistive element and a resistance of an external resistive element, said first and second control signals being adapted to cause an output impedance of the output driver to be substantially the same as or proportional to the resistance of the external resistive element.

2. The control circuit of claim 1 wherein said first circuit is responsive to the at least one internal resistive element and the external resistive element to generate first, second, third and fourth currents, said second current being proportional to the first current and being defined by the ratio of the resistances of the at least one internal resistive element and the external resistive element, said fourth current being proportional to the third current and being defined by the ratio of the resistances of the at least one internal resistive element and the external resistive element, said control circuit further comprising:
a second circuit adapted to generate fifth and sixth currents in response to the first and second currents and further in response to a first feedback signal, said sixth current being proportional to the fifth current;
a third circuit adapted to generate seventh and eight currents in response to the third and fourth currents and further in response to a second feedback signal, said eight current being proportional to the seventh current;
a fourth circuit adapted to generate the first feedback signal in response to the fifth and sixth currents and further in response to a ratio of a first pair of impedances; and
a fifth circuit adapted to generate the second feedback signal in response to the seventh and eight currents and further in response to a ratio of a second pair of impedances; wherein the output driver circuit is responsive to the fourth and fifth circuits.

3. The control circuit of claim 2 wherein said first circuit comprises:
a first amplifier responsive to the internal and the external resistances;
a second amplifier responsive to the external resistance;
first and second current mirrors responsive to the first amplifier to generate the first and second currents; and
third and fourth current mirrors responsive to the second amplifier to generate the third and fourth currents.

4. The control circuit of claim 3 wherein said second circuit comprises:
first and second variable resistors each having a resistance that varies in response to the first feedback signal;
a third amplifier responsive to the first variable resistor and to the first current;
a fourth amplifier responsive to the second variable resistor and to the second current;
a fifth current mirror responsive to the third amplifier to generate the fifth current; and
a sixth current mirror responsive to the fourth amplifier to generate the sixth current.

5. The control circuit of claim 4 wherein said third circuit comprises:
third and fourth variable resistors each having a resistance that varies in response to the second feedback signal;
a fifth amplifier responsive to the third variable resistor and to the third current;
a sixth amplifier responsive to the fourth variable resistor and to the fourth current;
a seventh current mirror responsive to the fifth amplifier to generate the seventh current; and
an eight current mirror responsive to the sixth amplifier to generate the eight current.

6. The control circuit of claim 5 wherein said fourth circuit comprises:
a seventh amplifier adapted to generate the first feedback signal in response to the fifth current and to the ratio of the first pair of impedances; and
an eighth amplifier adapted to generate a first control signal in response to the fifth and sixth currents, said output driver circuit comprising a first transistor circuit being responsive to the first control signal.

7. The control circuit of claim 6 wherein said fifth circuit comprises:
a ninth amplifier adapted to generate the second feedback signal in response to the seventh current and to the ratio of the second pair of impedances; and
a tenth amplifier adapted to generate a second control signal in response to the seventh and eight currents, said output circuit driver comprising a second transistor being responsive to the second control signal.

8. The control circuit of claim 7 wherein said fourth circuit further comprises a first MOS transistor disposed between input and output terminals of the eight amplifier.

9. The control circuit of claim 8 wherein said fifth circuit further comprises a second MOS transistor disposed between input and output terminals of the tenth amplifier.

10. The control circuit of claim 9 further comprising:
a comparator responsive to a pair of differential input signals.

11. The control circuit of claim 10 further comprising:
a first level shifter responsive to the comparator; and
a second level shifter responsive to the comparator.

12. The control circuit of claim 11 further comprising:
a first driver buffer responsive to the first control signal and the first level shifter to generate a first output signal having a level defined by the first control signal; and
a second driver buffer responsive to the second control signal and the second level shifter to generate a second output signal having a level defined by the second control signal.

13. The control circuit of claim 12 wherein said output driver comprises:
a PMOS transistor responsive to the first driver buffer; and
an NMOS transistor responsive to the second driver buffer.

14. The control circuit of claim 1 further comprising:
a first buffer responsive to the fourth circuit; and
a second buffer responsive to the fifth circuit.

15. A method of controlling an output impedance of a circuit, the method comprising:
generating first and second currents in response to voltages applied to an external resistance and to an internal resistance, said second current being proportional to the first current and being defined by a ratio of the external and internal resistances;
generating third and fourth currents in response to the voltages applied to the external resistance and the internal resistance, said fourth current being proportional to the third current and being defined by the ratio of the external and internal resistances;
generating a first control signal in response to the first and second currents;
generating a second control signal in response to the third and fourth currents; and
varying an output impedance of the circuit in response to the first and second control signals.

16. The method of claim 15 further comprising:
generating fifth and sixth currents in response to the first and second currents and further in response to a first feedback signal, said sixth current being proportional to the fifth current;
generating seventh and eight currents in response to the third and fourth currents and further in response to a second feedback signal, said eight current being proportional to the seventh current;
generating the first feedback signal and a first control signal in response to the fifth and sixth currents;
generating the second feedback signal and a second control signal in response to the seventh and eight currents.

17. The method of claim 16 further comprising:
mirroring the first current to generate the fifth current; and
mirroring the second current to generate the sixth current.

18. The method of claim 16 further comprising:
mirroring the third current to generate the seventh current; and
mirroring the fourth current to generate the eight current.

19. The method of claim 16 further comprising:
varying first and second resistances in response to the first feedback signal, said fifth and sixth currents being responsive to the first feedback signal; and
setting an output impedance of a first transistor in accordance with the external resistance and the first and second resistances.

20. The method of claim 19 further comprising:
varying third and fourth resistances in response to the second feedback signal, said seventh and eight currents being responsive to the second feedback signal; and
setting an output impedance of a second transistor in accordance with the external resistance and the third and fourth resistances.

21. The method of claim 20 further comprising:
comparing a first differential signal to a second differential signal to generate a comparison signal;
shifting voltage level of the comparison signal to generate a first level-shifted signal; and
shifting voltage level of the comparison signal to generate a second level-shifted signal

22. The method of claim 19 further comprising:
generating a first output signal in response to the first level-shifted signal, said first output signal having a level defined by the first control signal; and
generating a second output signal in response to the second level-shifted signal, said second output signal having a level defined by the second control signal.

23. The method of claim 22 further comprising:
applying the first output signal to a first MOS transistor;
applying the second output signal to a second MOS transistor.

24. The method of claim 23 further comprising:
buffering the first and second control signals.

25. A digital camera comprising:
a charge coupled device (CCD);
a clock generator;
a lens; and
a CCD driver comprising:
at least one resistive element;
an output driver; and
a first circuit adapted to generate a first control signal and a second control signal in response to a ratio of resistance of the at least one resistive element and a resistance of an external resistive element, said first and second control signals being adapted to cause an output impedance of the output driver to be substantially the same as or proportional to the resistance of the external resistive element.
